(19) United States
(12) Patent Application Publication
(10) Pub. No.: US 2017/0279032 A1
(43) Pub. Date: Sep. 28, 2017

(54) PIEZOELECTRIC ACTUATOR, STACKED ACTUATOR, PIEZOELECTRIC MOTOR, ROBOT, HAND, AND PUMP

(71) Applicant: Seiko Epson Corporation, Tokyo (JP)

(72) Inventor: Yuichiro TSUYUKI, Matsumoto (JP)

(21) Appl. No.: 15/463,408

(22) Filed: Mar. 20, 2017

(30) Foreign Application Priority Data
Mar. 22, 2016 (JP) 2016-056602

(51) Int. Cl. H01L 41/09; B06B 1/06; H01L 41/053

(52) U.S. Cl. CPC H01L 41/09; H01L 41/053; B06B 1/0611; Y10S 901/19

(57) ABSTRACT

A piezoelectric actuator includes a vibrating section configured to flexurally vibrate in an in-plane direction, a connecting section connected to the vibrating section in the vibrating direction of the vibrating section, a supporting section configured to support the vibrating section via the connecting section, and a reinforcing section provided on an opposite side of the vibrating section in the supporting section in a direction parallel to a direction in which the vibrating section and the connecting section are arranged.

### BACKGROUND

1. Technical Field

The present invention relates to a piezoelectric actuator and a stacked actuator, a piezoelectric motor, a robot, a hand, and a pump including the piezoelectric actuator.

2. Related Art

There has been known a piezoelectric actuator including a displacement mechanism section (a vibrating section), to which a piezoelectric element for driving is stuck, and a supporting section (e.g., JP-A-2001-111128 (Patent Literature 1)). When the piezoelectric element for driving receives an input of a driving signal, distortion occurs in the piezoelectric element for driving to cause the displacement mechanism section to vibrate with respect to the supporting section.

In the technique described above, it is likely that damage such as a crack occurs on the outer side, which is the opposite side of the vibrating section, of the supporting section because of the vibration of the vibrating section. In particular, it is likely that damage such as a crack occurs when the supporting section is formed of a fragile material.

### SUMMARY

An advantage of some aspects of the invention is to solve at least a part of the problems described above, and the invention can be implemented as the following forms.

(1) According to an aspect of the invention, a piezoelectric actuator is provided. The piezoelectric actuator includes: a vibrating section configured to flexurally vibrate in an in-plane direction; a connecting section connected to the vibrating section in the vibrating direction of the vibrating section; a supporting section configured to support the vibrating section via the connecting section; and a reinforcing section provided on an opposite side of the vibrating section in the supporting section in a direction parallel to a direction in which the vibrating section and the connecting section are arranged.

According to the aspect, the piezoelectric actuator includes the reinforcing section provided on a surface of the supporting section on the opposite side of the vibrating section. Therefore, it is possible to reduce, with the reinforcing section, occurrence of a crack of the supporting section due to the vibration of the vibrating section.

(2) In the piezoelectric actuator according to the aspect, the supporting section may include a fragile material.

When the supporting section includes the fragile material, a crack easily occurs. Therefore, a crack occurrence reducing effect by the reinforcing section is large.

(3) In the piezoelectric actuator according to the aspect, the vibrating section, the connecting section, and the supporting section may be integral.

According to the aspect with this configuration, since the vibrating section, the connecting section, and the supporting section are integral, manufacturing of the piezoelectric actuator is easy.

(4) In the piezoelectric actuator according to the aspect, the reinforcing section may include resin.

According to the aspect with this configuration, since the reinforcing section includes resin, it is possible to easily reinforce the supporting section.

(5) In the piezoelectric actuator according to the aspect, the resin may have a characteristic of being cured by ultraviolet ray.

According to the aspect with this configuration, since the resin has the characteristic of being cured by the ultraviolet ray, heating and cooling are unnecessary. The resin can be easily applied to the supporting section and easily cured by radiating the ultraviolet ray on the resin.

(6) In the piezoelectric actuator according to the aspect, the reinforcing section may be provided in a tie-bar cut section of the supporting section.

According to the aspect with this configuration, the tie-bar cut section of the supporting section is easily damaged during a cut. Therefore, it is desirable to reinforce the tie-bar cut section of the supporting section with the reinforcing section.

(7) According to another aspect of the invention, a stacked actuator is provided. In the stacked actuator, a plurality of the piezoelectric actuators according to the aspect explained above are stacked.

According to the aspect, it is possible to increase a driving force.

The invention can be realized in various forms. Besides a piezoelectric driving device and a piezoelectric actuator, the invention can be realized in various forms such as a piezoelectric motor, a robot including the piezoelectric motor, a hand including the piezoelectric motor, and a pump including the piezoelectric motor.

### BRIEF DESCRIPTION OF THE DRAWINGS

The invention will be described with reference to the accompanying drawings, wherein like numbers reference like elements.

FIG. 1 is a plan view showing a schematic configuration of a piezoelectric driving device in a first embodiment.

FIG. 2 is an explanatory view showing an example in which the piezoelectric driving device is used as a piezoelectric motor.

FIG. 3 is a plan view showing piezoelectric driving devices formed on a substrate in a stage halfway in a manufacturing process.

FIG. 4 is an explanatory view showing the substrate after etching.

FIG. 5 is an enlarged explanatory view showing a region near tie bars in FIG. 4.

FIG. 6 is an enlarged explanatory view showing a region near a tie-bar cut section after a tie-bar cut.

FIG. 7 is an explanatory view showing a state in which a reinforcing section is provided in the tie-bar section.

FIG. 8 is a plan view showing a schematic configuration of a piezoelectric driving device in a second embodiment.

FIG. 9 is a plan view showing a schematic configuration of a piezoelectric driving device in a third embodiment.

FIG. 10 is an explanatory view showing an example of a robot.

FIG. 11 is an explanatory view of a wrist portion of the robot.

FIG. 12 is an explanatory view showing a finger assist device.

FIG. 13 is an explanatory view showing an example of a pump.

### DESCRIPTION OF EXEMPLARY EMBODIMENTS

### First Embodiment

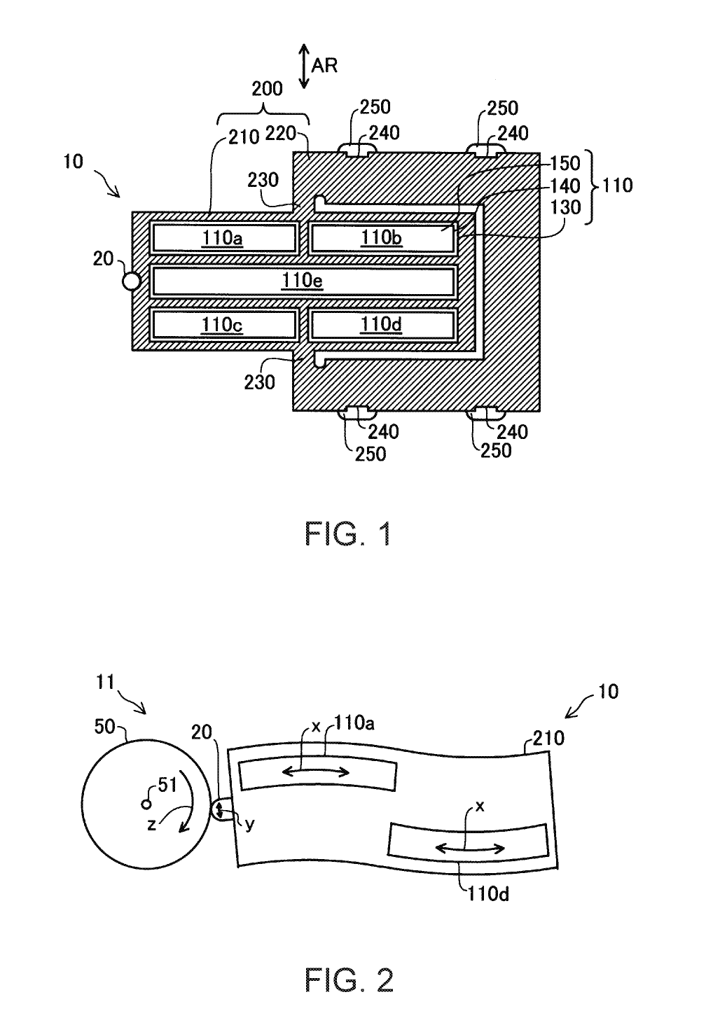

FIG. 1 is a plan view showing a schematic configuration of a piezoelectric driving device (a piezoelectric actuator) 10 in a first embodiment. The piezoelectric driving device 10 includes a substrate 200 and a piezoelectric element 110. For convenience of illustration, the substrate 200 is hatched. The substrate 200 includes a vibrating section 210, a supporting section 220, and connecting sections 230. The vibrating section 210 is a substantially rectangular member. The piezoelectric element 110 is placed on the vibrating section 210.

A contactor 20 in contact with a driven member is provided in one short side of two short sides of the vibrating section 210. The supporting section 220 is disposed to surround an approximately half of the vibrating section 210 on the opposite side of the contactor 20 in the vibrating section 210. The supporting section 220 is connected to the vibrating section 210 by the connecting sections 230 substantially in the center of a long side of the vibrating section 210. The supporting section 220 supports the vibrating section 210. When viewed in a direction parallel to a direction AR in which the vibrating section 210 and the connecting sections 230 are arranged, the supporting section 220 includes tie-bar cut sections 240 on surfaces (side surfaces) of the supporting section 220 on the opposite sides of the vibrating section 210. Reinforcing sections 250 are provided to cover the tie-bar cut sections 240. The tie-bar cut sections 240 are traces of cutting of tie bars during manufacturing. This point is explained below. When the vibrating section 210 vibrates according to expansion and contraction of the piezoelectric element 110, the tie-bar cut sections 240 are easily cracked by the vibration. Therefore, the reinforcing sections 250 are provided to reduce occurrence of the crack. The reinforcing sections 250 desirably include resin. As the resin, it is desirable to use ultraviolet-curing resin. Heating and cooling are unnecessary to cure and soften the ultraviolet curing resin. It is possible to reduce the influence of heat. It is possible to easily cure the ultraviolet curing resin by applying, using, for example, potting, the resin before curing and radiating the ultraviolet ray on the resin. Therefore, it is possible to easily form the reinforcing sections 250. Note that the reinforcing sections 250 can also be referred to as “protection films”.

The piezoelectric element 110 includes a first electrode 130 (referred to as “first electrode film 130” as well because the first electrode 130 is formed in a film shape), a piezoelectric body 140 (referred to as “piezoelectric body film 140” as well because the piezoelectric body 140 is formed in a film shape) formed on the first electrode 130, and a second electrode 150 (referred to as “second electrode film 150” as well because the second electrode 150 is formed in a film shape) formed on the piezoelectric body 140. The first electrode 130 and the second electrode 150 sandwiches the piezoelectric body 140. The first electrode 130 and the second electrode 150 are, for example, thin films formed by sputtering. As the material of the first electrode 130 and the second electrode 150, it is possible to use any materials having high electric conductivity such as Al (aluminum), Ni (nickel), Au (gold), Pt (platinum), Ir (iridium), and Cu (copper).

The piezoelectric body 140 is formed by, for example, the sol-gel method or the sputtering method and has a thin-film shape. As the material of the piezoelectric body 140, it is possible to use any materials showing a piezoelectric effect such as ceramics that adopt a perovskite structure of an ABO₃ type. As the ceramics that adopt the perovskite structure of the ABO₃ type, it is possible to use, for example, lead zirconate titanate (PZT), barium titanate, lead titanate, potassium niobate, lithium niobate, lithium tantalate, sodium tungstate, zinc oxide, barium strontium titanate (BST), strontium bismuth tantalate (SBT), lead metaniobate, lead zinc niobate, and scandium lead niobate. It is also possible to use materials showing the piezoelectric effect other than the ceramics, for example, polyvinylidene fluoride and quartz. The thickness of the piezoelectric body 140 is desirably set in a range of, for example, 50 nm (0.05 μm) or more and 20 μm or less. A thin film of the piezoelectric body 140 having the thickness in this range can be easily formed using a film forming process (referred to as “film forming process” as well). If the thickness of the piezoelectric body 140 is set to 0.05 μm or more, it is possible to generate a sufficiently large force according to expansion and contraction of the piezoelectric body 140. If the thickness of the piezoelectric body 140 is set to 20 μm or less, it is possible to sufficiently reduce the piezoelectric driving device 10 in size. However, it is unnecessary to form the piezoelectric body 140 as the thin film. The piezoelectric body 140 may be formed as a film having thickness larger than the thickness explained above. As the piezoelectric body 140, it is also possible to use a bulky piezoelectric body.

In the first embodiment, the piezoelectric driving device 10 includes five piezoelectric elements 110a, 110b, 110c, 110d, and 110e as the piezoelectric element 110. The piezoelectric element 110e is formed in a substantially rectangular shape and is formed along the longitudinal direction of the vibrating section 210 in the center in the width direction of the vibrating section 210. The piezoelectric elements 110a, 110b, 110c, and 110d are formed in the positions of the four corners of the vibrating section 210. Note that, in FIG. 1, an example is shown in which the piezoelectric element 110 is formed on one surface of the vibrating section 210. However, the piezoelectric elements 110 may be formed on two surfaces of the vibrating section 210. In this case, the piezoelectric elements 110a to 110e on one surface and the piezoelectric elements 110a to 110e on the other surface are desirably disposed symmetrically with respect to the vibrating section 210 set as a plane of symmetry.

The substrate 200 is used as a substrate for forming the first electrode 130, the piezoelectric body 140, and the second electrode 150 in a film forming process. The vibrating section 210 of the substrate 200 also has a function of a vibrating plate that performs mechanical vibration. The substrate 200 can be formed of, for example, Si, Al₂O₃, and ZrO₂, which are fragile materials. As the substrate 200 made of silicon (Si) (referred to as “silicon substrate 200” as well), for example, it is possible to use an Si wafer for semiconductor manufacturing. The thickness of the substrate 200 is desirably set in a range of, for example, 10 μm or more and 100 μm or less. If the thickness of the substrate 200 is set to 10 μm or more, it is possible to relatively easily handle the substrate 200 in film formation treatment on the substrate 200. Note that, if the thickness of the substrate 200 is set to 50 μm or more, it is possible to more easily handle the substrate 200. If the thickness of the substrate 200 (the vibrating section 210) is set to 100 μm or less, it is possible to easily cause the vibrating section 210 to vibrate according to expansion and contraction of the piezoelectric body 140 formed by the thin film.

FIG. 2 is an explanatory view showing an example in which the piezoelectric driving device 10 is used as a piezoelectric motor 11. The contactor 20 of the piezoelectric driving device 10 is in contact with the outer circumference of a rotor 50 functioning as a driven member and forms the piezoelectric motor 11. In the example shown in FIG. 2, an alternating voltage or an undulating voltage is applied to two piezoelectric elements 110a and 110d. The piezoelectric elements 110a and 110d expand and contract in a direction of an arrow x. According to the expansion and contraction of the piezoelectric elements 110a and 110d, the vibrating section 210 of the piezoelectric driving device 10 flexurally vibrates in the plane of the vibrating section 210 to be deformed in a meandering shape (an S shape). The distal end of the contactor 20 reciprocatingly moves in a direction of an arrow y or elliptically moves. As a result, the rotor 50 rotates in a predetermined direction z (in FIG. 2, the clockwise direction) around a center 51 of the rotor 50. Note that, when an alternating voltage or an undulating voltage is applied to two piezoelectric elements 110b and 110c, the rotor 50 rotates in the opposite direction (the counterclockwise direction). Note that, if an alternating voltage or an undulating voltage is applied to the piezoelectric element 110e in the center, the piezoelectric driving device 10 expands and contracts in the longitudinal direction. Therefore, it is possible to further increase a force applied from the contactor 20 to the rotor 50. Note that such operation of the piezoelectric driving device 10 is described in Patent Literature 1 described above (JP-A-2004-320979 or U.S. Pat. No. 7,224,102 corresponding thereto), disclosed content of which is incorporated herein by reference.

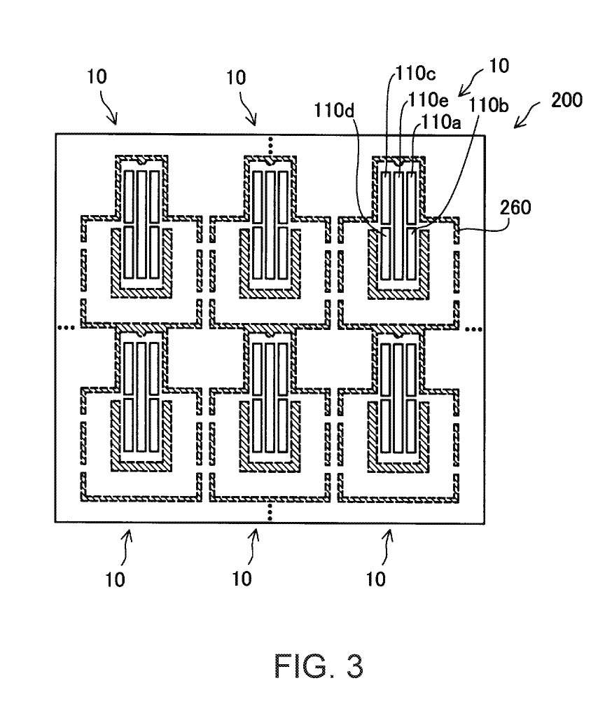

FIG. 3 is a plan view showing piezoelectric driving devices 10 formed on the substrate 200 in a stage halfway in a manufacturing process. Concerning a process for forming the piezoelectric driving devices 10 on the substrate 200, a thin-film manufacturing process can be used. Therefore, explanation of the process is omitted. In FIG. 3, six piezoelectric driving devices 10 in total in two rows and three columns are shown on the substrate 200. However, actually, an extremely large number of piezoelectric driving devices 10 are two-dimensionally formed on the substrate 200. In FIG. 3, for convenience of illustration, in only the piezoelectric driving device 10 on the upper right, the piezoelectric elements are denoted by reference signs 110a to 110e. However, the piezoelectric driving devices 10 include the piezoelectric elements 110a to 110e. Regions indicated by hatching on the inner sides of broken lines shown in FIG. 3 indicate etching regions 260 to be removed by etching.

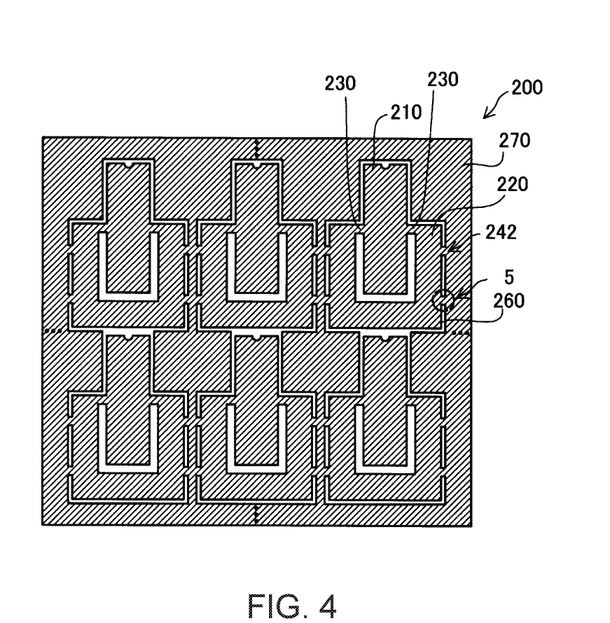

FIG. 4 is an explanatory view showing the substrate 200 after the etching. Note that, in FIG. 4, only the substrate 200 is shown and the piezoelectric elements 110a to 110e are not shown. A region indicated by hatching is a region left by the hatching. That is, when the substrate 200 is etched, the vibrating section 210, the supporting section 220, the connecting sections 230, tie bars 242, and a frame section 270 are left. The vibrating section 210, the supporting section 220, and the connecting sections 230 are formed as an integral member. The supporting section 220 of each of the piezoelectric driving device 10 is connected to the frame section 270 by the tie bars 242 in four parts. In the following process, a singulated piezoelectric driving device 10 can be obtained by cutting the tie bars 242. Note that, when a stacked actuator explained below is configured, it is more efficient to stack the piezoelectric driving devices 10 in a state before being singulated and thereafter singulate the piezoelectric driving devices 10 to obtain stacked actuators rather than sigulating and then stacking the piezoelectric driving devices 10.

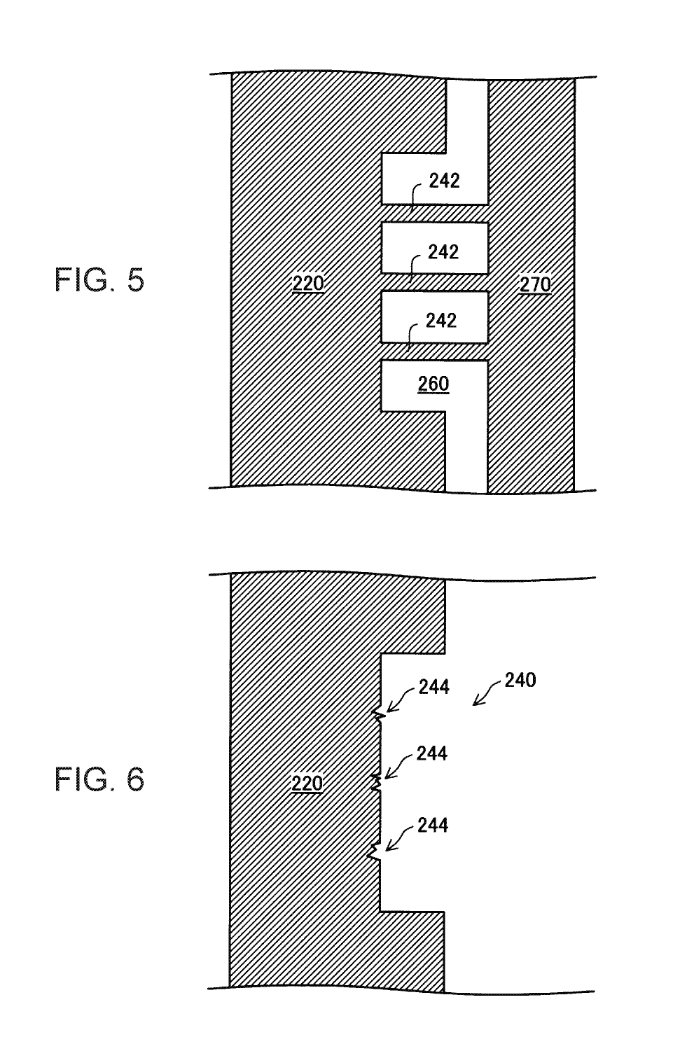

FIG. 5 is an enlarged explanatory view showing a region 5 near the tie bars 242. The tie bars 242 are bar-like portions that connect the supporting section 220 and the frame section 270. In the first embodiment, three tie bars 242 are provided. The number of the tie bars 242 may be any number as long as the number is equal to or larger than 1. In the first embodiment, a recessed section is provided in the supporting section 220 and the bottom of the recessed section and the frame section 270 are connected by the tie bars 242. However, the flat supporting section 220 and the frame section 270 may be connected by the tie bars 242 without providing the recessed section.

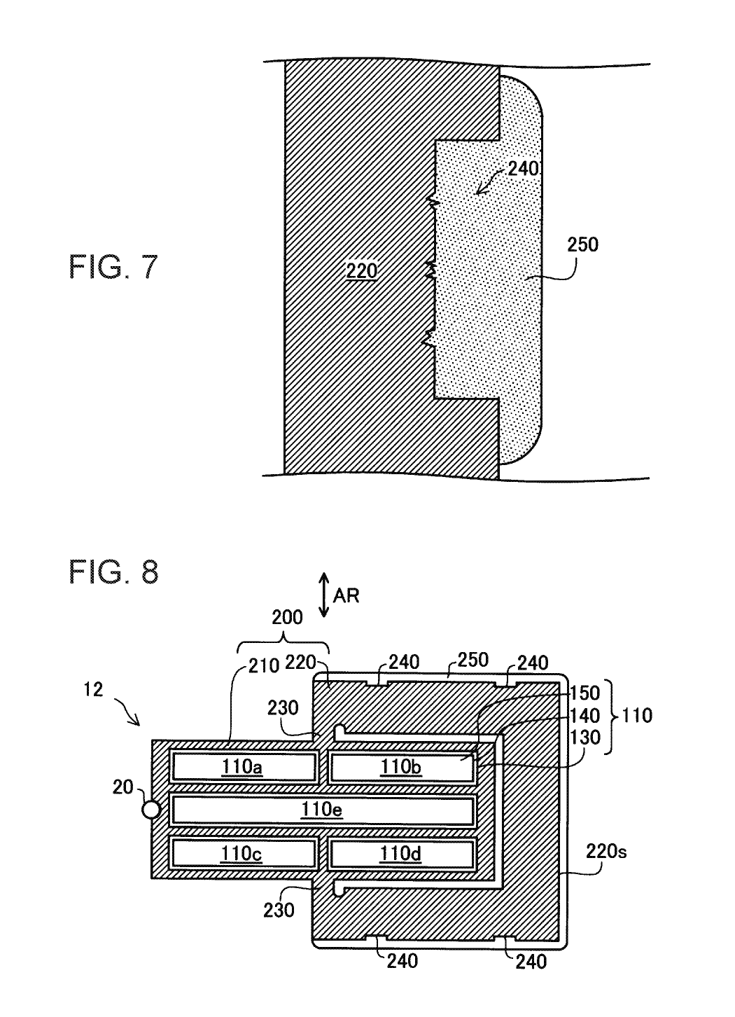

FIG. 6 is an enlarged explanatory view showing a region near the tie-bar cut section 240 after the tie-bar cut. For example, the tie bars 242 (FIG. 5) are snapped to be cut by pressing of a bar-like jig, cut by outer peripheral teeth like dicing, or cut by a laser. A trace of the cutting of the tie bars 242 is the tie-bar cut section 240. When the tie bars 242 are cut, since stress is applied to the tie-bar cut section 240, cracks easily occur in the tie-bar cut section 240. Ruptured surfaces 244 of the tie bars 242 are easily roughened. When the stress is applied to the tie bars 242, cracks easily occur starting from the ruptured surfaces 244. When the reinforcing section 250 is formed in the tie-bar cut section 240 after the tie bars 242 are cut, the tie-bar cut section 240 is less easily deformed even if the stress is applied to the tie-bar cut section 240. The cracks less easily spread from the ruptured surfaces 244.

FIG. 7 is an explanatory view showing a state in which the reinforcing section 250 is provided in the tie-bar cut section 240. In the first embodiment, when the vibrating section 210 (FIG. 1) vibrates, as explained above, cracks easily occur in the tie-bar cut section 240. The cracks are likely to spread. In the first embodiment, in order to reduce the occurrence and the spread of the cracks, the reinforcing section 250 is provided in the tie-bar cut section 240. Even if stress is applied to the tie-bar cut section 240, deformation of the tie-bar cut section 240 is reduced by the reinforcing section 250. Therefore, it is possible to reduce the occurrence of the cracks that starts from the tie-bar cut section 240. Note that, as explained above, the reinforcing section 250 includes resin. It is desirable to use resin having an ultraviolet curing characteristic as the resin.

As the material of the reinforcing section 250, a material other than the resin can be used. For example, a rigid insulating film formed by the CVD method may be used as the reinforcing section 250. It is desirable to form the reinforcing section 250 from an insulating material because the insulation of the substrate 200 is improved.

As explained above, according to the first embodiment, the piezoelectric driving device 10 includes the reinforcing sections 250 in the tie-bar cut sections 240. Therefore, it is possible to reduce occurrence of cracks in the supporting section 220 and spread of the cracks. In particular, when the supporting section 220 is formed of a fragile material, the piezoelectric driving device 10 is effective because cracks easily occur.

In the first embodiment, the example is explained in which the supporting section 220 includes the tie-bar cut sections 240. However, a cause of cracks does not depend on the tie-bar cut sections 240. In the first embodiment, the vibrating section 210 flexurally vibrates in an in-plane direction thereof (a direction parallel to the surface formed by the vibrating section 210). The supporting section 220 is connected to the vibrating section 210 via the connecting sections 230 in the vibrating direction of the vibrating section 210. In this case, stress due to the vibration of the vibrating section 210 is transmitted to the supporting section 220 via the connecting sections 230. Cracks sometimes occur on surfaces of the supporting section 220 on the opposite sides of the vibrating section 210 in a direction parallel to a direction in which the vibrating section 210 and the connecting sections 230 are arranged (because of the vibrating direction). Therefore, even when the supporting section 220 does not include the tie-bar cut sections 240, if the reinforcing sections 250 are provided on the surfaces of the supporting section 220 on the opposite sides of the vibrating section 210 in the direction parallel to the direction in which the vibrating section 210 and the connecting sections 230 are arranged, it is possible to reduce the occurrence of the cracks (due to the vibrating direction). When the supporting section 220 includes the tie-bar cut sections 240 and the supporting section 220 is connected to the vibrating section 210 via the connecting sections 230 in the vibrating direction of the vibrating section 210, the effect of the reinforcing sections 250 reducing the occurrence of the cracks is larger.

### Second Embodiment

FIG. 8 is a plan view showing a schematic configuration of a piezoelectric driving device 12 in a second embodiment. The piezoelectric driving device 10 in the first embodiment includes the reinforcing sections 250 in the tie-bar cut sections 240. The piezoelectric driving device 12 in the second embodiment includes the reinforcing section 250 over an entire surface (side surfaces) on the outer edge side of the supporting section 220, that is, on the opposite sides of the vibrating section 210. Since the reinforcing section 250 is provided over a wide range of the outer circumference of the supporting section 220, it is possible to further reduce occurrence of cracks in the supporting section 220. In the second embodiment, as in the first embodiment, the reinforcing section 250 covers the tie-bar cut sections 240. The reinforcing section 250 does not have to be provided on a side surface 220s parallel to a short side of the vibrating section 210 among the side surfaces on the outer edge side of the supporting section 220. This is because a wiring board explained below is sometimes connected to the side surface 220s.

### Third Embodiment

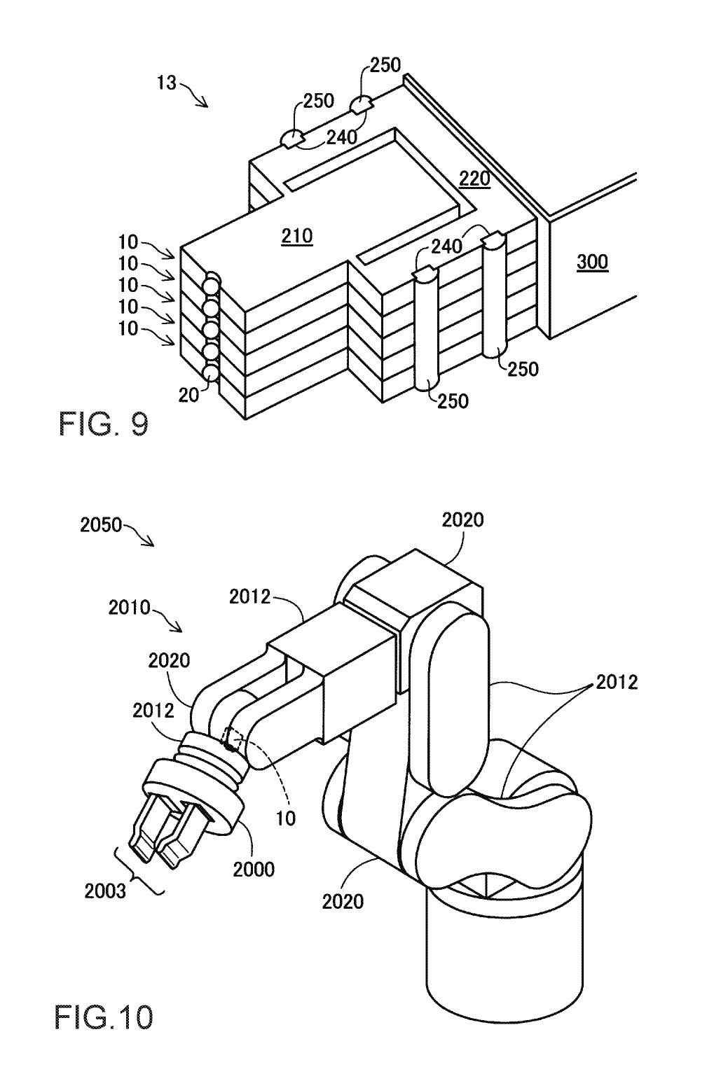

FIG. 9 is a plan view showing a schematic configuration of a stacked actuator 13 in a third embodiment. The stacked actuator 13 includes a plurality of (in FIG. 9, five) stacked piezoelectric driving devices 10 and a wiring board 300 for supplying electric power for the piezoelectric driving devices 10. The wiring board 300 is configured by, for example, a flexible board. Note that the reinforcing section 250 of the stacked actuator 13 has a shape extending along a stacking direction of the piezoelectric driving devices 10. Like the piezoelectric driving device 10 in the first embodiment, the stacked actuator 13 includes the reinforcing sections 250 in the tie-bar cut sections 240. Therefore, it is possible to reduce occurrence of cracks in the supporting section 220 and spread of the cracks. Note that, instead of the piezoelectric driving devices 10 in the first embodiment, a plurality of piezoelectric driving devices 12 in the second embodiment may be stacked.

### Other embodiments

The piezoelectric driving devices 10 and 12 and the stacked actuator 13 (in the embodiments explained below, the term “piezoelectric driving device 10” is representatively used) can apply a large force to a driven member using resonance. The piezoelectric driving device 10 is applicable to various apparatuses as a piezoelectric motor. The piezoelectric driving device 10 can be used as a driving device in various apparatuses such as a robot (including an electronic component conveying apparatus (an IC handler)), a pump for medication, a calendar feeding device of a clock, and a printing apparatus (e.g., a paper feeding mechanism). Representative embodiments are explained below.

FIG. 10 is an explanatory view showing an example of a robot 2050 including the piezoelectric driving device 10. The robot 2050 includes an arm 2010 (referred to as “arm section” as well) including a plurality of link sections 2012 (referred to as “link members” as well) and a plurality of joint sections 2020 that connect the link sections 2012 in a turnable or bendable state. The piezoelectric driving devices 10 are incorporated in the respective joint sections 2020. It is possible to turn or bend the joint sections 2020 at any angles using the piezoelectric driving devices 10. Note that, in FIG. 10, for convenience of illustration, only one piezoelectric driving device 10 is shown. A hand 2000 is connected to the distal end of the arm 2010. The hand 2000 includes a pair of gripping sections 2003. The piezoelectric driving device 10 is incorporated in the hand 2000 as well. It is possible to open and close the gripping sections 2003 to grip an object using the piezoelectric driving device 10. The piezoelectric driving device 10 is provided between the hand 2000 and the arm 2010 as well. It is also possible to rotate the hand 2000 with respect to the arm 2010 using the piezoelectric driving device 10.

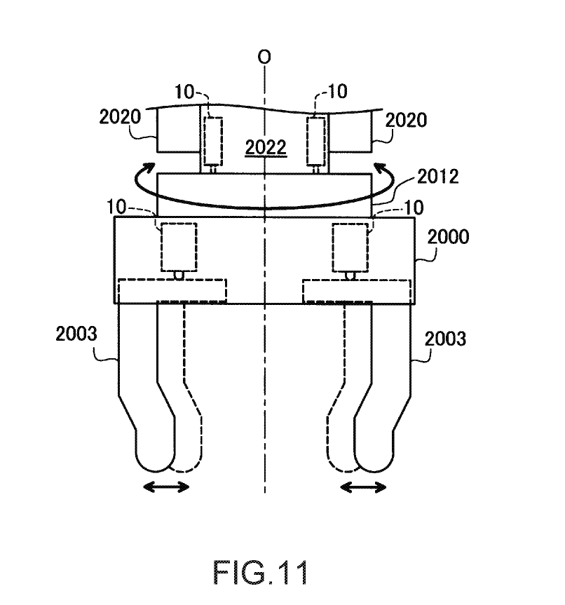

FIG. 11 is an explanatory view of a wrist portion of the robot 2050 shown in FIG. 10. The joint sections 2020 of the wrist sandwich a wrist turning section 2022. The link section 2012 of the wrist is attached to the wrist turning section 2022 to be capable of turning around a center axis O of the wrist turning section 2022. The wrist turning section 2022 includes the piezoelectric driving device 10. The piezoelectric driving device 10 causes the link section 2012 of the wrist and the hand 2000 to turn around the enter axis O. A plurality of gripping sections 2003 are erected on the hand 2000. The proximal end sections of the gripping sections 2003 are movable in the hand 2000. The piezoelectric driving devices 10 are mounted on base portions of the gripping sections 2003. Therefore, it is possible to move the gripping sections 2003 and grip a target object by operating the piezoelectric driving devices 10.

Note that the robot is not limited to a single-arm robot. The piezoelectric driving device 10 is applicable to a multi-arm robot including two or more arms. On the insides of the joint section 2020 of the wrist and the hand 2000, besides the piezoelectric driving devices 10, power lines for supplying electric power to various devices such as a force sensor and a gyro sensor, signal lines for transmitting signals, and the like are included. Extremely large number of wires are necessary. Therefore, it has been extremely difficult to dispose the wires on the insides of the joint sections 2020 and the hand 2000. However, the piezoelectric driving device 10 in the embodiment explained above can reduce a driving current more than a normal electric motor and a piezoelectric driving device in the past. Therefore, it is possible to dispose the wires even in small spaces such as the joint sections 2020 (in particular, the joint section at the distal end of the arm 2010) and the hand 2000.

In the above explanation, the robot 2050 including the hand 2000 is explained as the example. However, the hand 2000 may be configured not only as a component of the robot 2050 but also as an independent product.

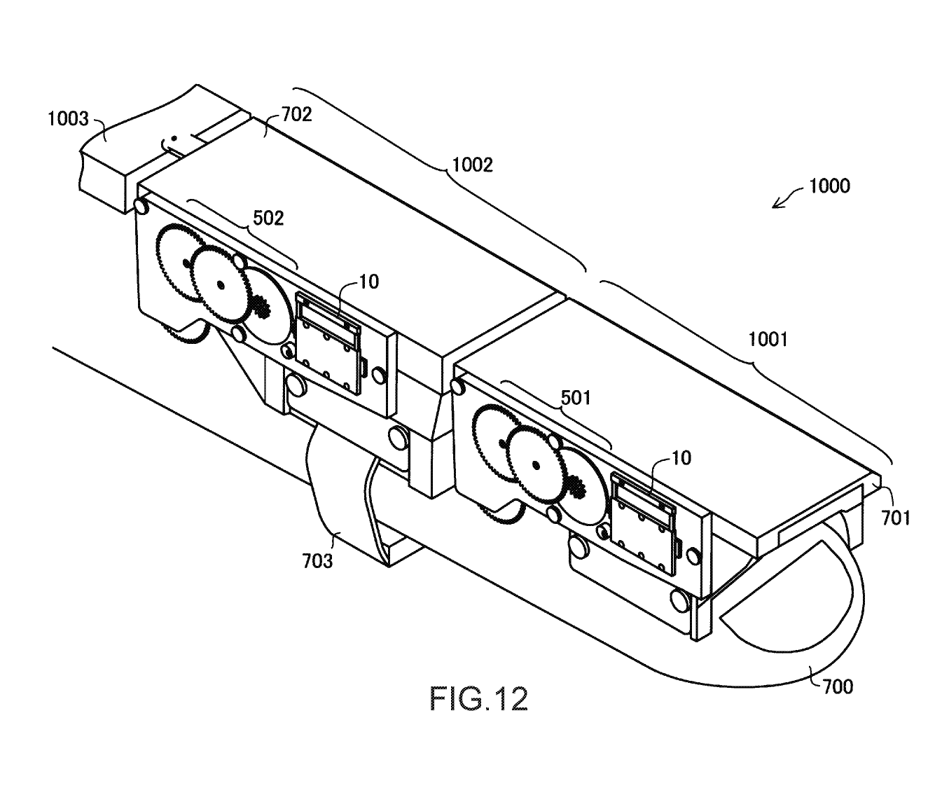

FIG. 12 is an explanatory view showing a finger assist device 1000 including the piezoelectric driving devices 10. The finger assist device 1000 includes a first finger assist section 1001, a second finger assist section 1002, and a base member 1003. The finger assist device 1000 is worn on a finger 700. The first finger assist section 1001 includes the piezoelectric driving device 10, a reduction gear 501, and a finger supporting section 701. The second finger assist section 1002 includes the piezoelectric driving device 10, a reduction gear 502, a finger supporting section 702, and a band 703. The first finger assist section 1001 and the second finger assist section 1002 have substantially the same configuration except the band 703. The band 703 fixes the second finger assist section 1002 from the pad side of the finger 700. Note that the band 703 is provided in the first finger assist section 1001 as well. However, the band 703 is not shown in FIG. 12. The finger assist device 1000 assists bending and stretching of the finger 700 with the piezoelectric driving devices 10. Note that, in this embodiment, the finger assist device 1000 is explained as assisting the bending and stretching of the finger 700. However, a hand of a robot may be used instead of the finger 700. The hand and the finger assist device 1000 may be integrated. In this case, the hand is driven by the piezoelectric driving device 10 and bent and stretched.

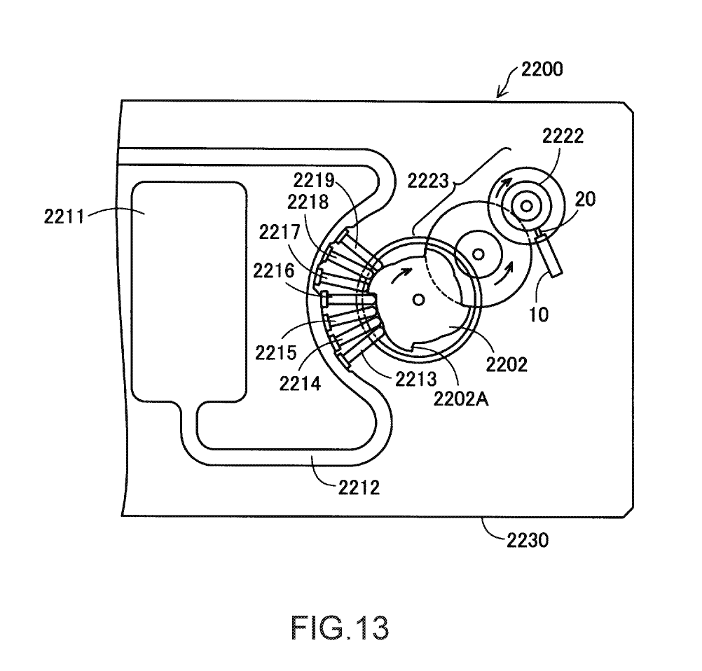

FIG. 13 is an explanatory view showing an example of a liquid feeding pump 2200 functioning as a pump including the piezoelectric driving device 10. In the liquid feeding pump 2200, a reservoir 2211, a tube 2212, the piezoelectric driving device 10, a rotor 2222, a speed reduction transmitting mechanism 2223, a cam 2202, and a plurality of fingers 2213, 2214, 2215, 2216, 2217, 2218, and 2219 are provided in a case 2230. The reservoir 2211 is a storing section for storing liquid to be transported. The tube 2212 is a tube for transporting the liquid delivered from the reservoir 2211. The contactor 20 of the piezoelectric driving device 10 is provided in a state in which the contactor 20 is pressed against a side surface of the rotor 2222. The piezoelectric driving device 10 is driven to rotate the rotor 2222. The torque of the rotor 2222 is transmitted to the cam 2202 via the speed reduction transmitting mechanism 2223. The fingers 2213 to 2219 are members for closing the tube 2212. When the cam 2202 rotates, the fingers 2213 to 2219 are pushed to the radial direction outer side in order by a protrusion section 2202A of the cam 2202. The fingers 2213 to 2219 close the tube 2212 in order from a transporting direction upstream side (the reservoir 2211 side). Consequently, the liquid in the tube 2212 is transported to a downstream side in order. Consequently, it is possible to accurately feed a very small amount of the liquid. Moreover, it is possible to realize the liquid feeding pump 2200 small in size. Note that the dispositions of the members are not limited to the disposition shown in the figure. The liquid feeding pump 2200 does not have to include the members such as the fingers. A ball or the like provided in the rotor 2222 may close the tube 2212. The liquid feeding pump 2200 explained above can be used for a drug delivery apparatus for administering a drug solution such as insulin to a human body. When the piezoelectric driving device 10 in this embodiment is used, since a driving current is smaller than the driving current in the piezoelectric driving device in the past, it is possible to reduce power consumption of the drug delivery apparatus. Therefore, the piezoelectric driving device is particularly effective when the drug delivery apparatus is driven by a battery.

The embodiments of the invention are explained above on the basis of the several examples. However, the embodiments of the invention explained above are explained to facilitate understanding of the invention and do not limit the invention. The invention can be changed and improved without departing from the spirit of the invention and appended claims. It goes without saying that equivalents of the invention are included in the invention.

The entire disclosure of Japanese Patent Application No. 2016-056602, filed Mar. 22, 2016 is expressly incorporated by reference herein.

What is claimed is:

1. A piezoelectric actuator comprising:
a vibrating section configured to flexurally vibrate in an in-plane direction;
a connecting section connected to the vibrating section in the vibrating direction of the vibrating section;
a supporting section configured to support the vibrating section via the connecting section; and
a reinforcing section provided on an opposite side of the vibrating section in the supporting section in a direction parallel to a direction in which the vibrating section and the connecting section are arranged.

2. The piezoelectric actuator according to claim 1, wherein the supporting section includes a fragile material.

3. The piezoelectric actuator according to claim 1, wherein the vibrating section, the connecting section, and the supporting section are integral.

4. The piezoelectric actuator according to claim 1, wherein the reinforcing section includes resin.

5. The piezoelectric actuator according to claim 4, wherein the resin has a characteristic of being cured by ultraviolet ray.

6. The piezoelectric actuator according to claim 1, wherein the reinforcing section is provided in a tie-bar cut section of the supporting section.

7. A stacked actuator, wherein a plurality of the piezoelectric actuators according to claim 1 are stacked.

8. A piezoelectric motor comprising the piezoelectric actuator according to claim 1.

9. A piezoelectric motor comprising the stacked actuator according to claim 7.

10. A robot comprising the piezoelectric motor according to claim 8.

11. A robot comprising the piezoelectric motor according to claim 9.

12. A hand comprising the piezoelectric motor according to claim 8.

13. A hand comprising the piezoelectric motor according to claim 9.

14. A pump comprising the piezoelectric motor according to claim 8.

15. A pump comprising the piezoelectric motor according to claim 9.
